(19) United States
(12) Patent Application Publication
(10) Pub. No.: US 2023/0226946 A1
(43) Pub. Date: Jul. 20, 2023

(54) ELECTRIFIED VEHICLE AND METHOD FOR PROVIDING DISTANCE TO EMPTY THEREOF

(71) Applicants: Hyundai Motor Company, Seoul (KR); Kia Corporation, Seoul (KR)

(72) Inventor: Dong Il Yang, Gwangmyeong (KR)

(21) Appl. No.: 17/890,050

(22) Filed: Aug. 17, 2022

(30) Foreign Application Priority Data
Jan. 17, 2022 (KR) 10-2022-0006684

(51) Int. Cl. B60L 58/12; H02J 7/00; G01R 31/374; G01R 31/382

(52) U.S. Cl. CPC B60L 58/12; H02J 7/0063; G01R 31/374; G01R 31/382; B60L 2260/52; B60L 2260/54; B60Y 2200/91

(57) ABSTRACT

The present disclosure relates to an electrified vehicle and a method for providing a distance to empty thereof that provide the distance to empty with a minimum error with an actual mileage. The electrified vehicle includes a temperature sensor for measuring an ambient temperature of the vehicle, a BMS for monitoring a SOC of a battery mounted on the vehicle, and a controller that calculates a DTE based on the ambient temperature and the SOC of the battery, adjusts a DTE reduction rate based on an actual discharging amount of the battery while traveling, and updates the DTE based on the adjusted DTE reduction rate.

### CROSS-REFERENCE TO RELATED APPLICATION

This application claims under 35 U.S.C. § 119(a) the benefit of priority to Korean Patent Application No. 10-2022-0006684, filed in the Korean Intellectual Property Office on Jan. 17, 2022, the entire contents of which is incorporated herein by reference.

### TECHNICAL FIELD

The present disclosure relates to an electrified vehicle and a method for providing a distance to empty thereof that provide a distance to empty with a minimum error with an actual mileage.

### BACKGROUND

In general, an electrified vehicle calculates a final distance to empty (DTE) by calculating a representative fuel efficiency through learning of a fuel efficiency of a driver, and then multiplying the representative fuel efficiency by a current available energy or an available energy predicted through air conditioning consumption power prediction. In such conventional DTE calculation scheme, the fuel efficiency learning may be possible only when a certain travel distance for identifying a driver tendency (an operation degree of the fuel efficiency) may be secured. The conventional DTE calculation scheme has a high probability of generating a travel error when a driving fuel efficiency may be deteriorated by a sudden change in a road type (a downtown↔a highway) or a sudden change in a weather. In addition, in the related art, because a discharging amount consumed for the air conditioning may be calculated using an average vehicle speed, when a vehicle speed may be suddenly changed, a change range of air conditioning energy may be excessive, which may be highly likely to cause the travel error.

### SUMMARY

The present disclosure has been made to solve the above-mentioned problems occurring in the existing technologies while advantages achieved by the existing technologies may be maintained intact.

An embodiment of the present disclosure provides an electrified vehicle and a method for providing a distance to empty thereof that calculate and provide the distance to empty of the vehicle in consideration of a battery state of charge (SOC) and an ambient temperature to minimize an error between a distance to empty and an actual mileage.

The technical problems to be solved by the present disclosure may not be limited to the aforementioned problems, and any other technical problems not mentioned herein will be clearly understood from the following description by those skilled in the art to which the present disclosure pertains.

According to an embodiment of the present disclosure, an electrified vehicle includes a temperature sensor for measuring an ambient temperature of the vehicle, a battery management system (BMS) for monitoring a SOC of a battery mounted on the vehicle, and a controller that calculates a distance to empty (DTE) based on the ambient temperature and the SOC of the battery, adjusts a DTE reduction rate based on an actual discharging amount of the battery while traveling, and updates the DTE based on the adjusted DTE reduction rate.

In one implementation, the controller may calculate an initial DTE based on a discharging amount matching the SOC of the battery and a fixed fuel efficiency of the vehicle, calculate a correction factor based on the ambient temperature, and calculate the DTE based on the initial DTE and the correction factor.

In one implementation, the discharging amount matching the SOC of the battery may be determined based on a battery discharging amount of when the battery may be fully charged.

In one implementation, the controller may compare the actual discharging amount of the battery with a first reference discharging amount, and determine the D reduction rate as a first D reduction rate when the actual discharging amount of the battery may be less than the first reference discharging amount.

In one implementation, the controller may compare the actual discharging amount of the battery with a second reference discharging amount when the actual discharging amount of the battery may be equal to or greater than the first reference discharging amount, and determine the DTE reduction rate as a second DTE reduction rate when the actual discharging amount of the battery may be less than the second reference discharging amount.

In one implementation, the controller may compare the actual discharging amount of the battery with a third reference discharging amount when the actual discharging amount of the battery may be equal to or greater than the second reference discharging amount, and determine the DTE reduction rate as a third DTE reduction rate when the actual discharging amount of the battery may be less than the third reference discharging amount.

In one implementation, the first reference discharging amount, the second reference discharging amount, and the third reference discharging amount may be determined based on remaining energy of the battery and a reference discharging amount determined by the DTE.

In one implementation, the controller may decrease the DTE with the DTE reduction rate and then update the DTE with the reduced DTE whenever the vehicle actually travels a predetermined distance.

In one implementation, the electrified vehicle may further include an output device for displaying the DTE.

In one implementation, the output device may include at least one of a cluster, an AVN terminal, a display, or a touch screen.

According to another embodiment of the present disclosure, a method for providing a distance to empty of an electrified vehicle includes calculating a DTE based on a SOC of a battery mounted on the vehicle and an ambient temperature of the vehicle, adjusting a DTE reduction rate based on an actual discharging amount of the battery while traveling, and updating the DTE based on the adjusted DTE reduction rate.

In one implementation, the calculating of the DTE may include acquiring the SOC of the battery through a BMS, calculating an initial DTE based on a discharging amount matching the SOC of the battery and a fixed fuel efficiency of the vehicle, calculating a correction factor based on the ambient temperature acquired by a temperature sensor, and calculating the DTE based on the initial DTE and the correction factor.

In one implementation, the discharging amount matching the SOC of the battery may be determined based on a battery discharging amount of when the battery may be fully charged.

In one implementation, the adjusting of the DTE reduction rate may include comparing the actual discharging amount of the battery with a first reference discharging amount, and determining the DTE reduction rate as a first DTE reduction rate when the actual discharging amount of the battery may be less than the first reference discharging amount.

In one implementation, the adjusting of the DTE reduction rate may include comparing the actual discharging amount of the battery with a second reference discharging amount when the actual discharging amount of the battery may be equal to or greater than the first reference discharging amount, and determining the DTE reduction rate as a second DTE reduction rate when the actual discharging amount of the battery may be less than the second reference discharging amount.

In one implementation, the adjusting of the DTE reduction rate may include comparing the actual discharging amount of the battery with a third reference discharging amount when the actual discharging amount of the battery may be equal to or greater than the second reference discharging amount, and determining the DTE reduction rate as a third DTE reduction rate when the actual discharging amount of the battery may be less than the third reference discharging amount.

In one implementation, the first reference discharging amount, the second reference discharging amount, and the third reference discharging amount may be determined based on remaining energy of the battery and a reference discharging amount determined by the DTE.

In one implementation, the updating of the DTE may include decreasing the DTE with the DTE reduction rate and then updating the DTE with the reduced DTE whenever the vehicle actually travels a predetermined distance.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating an electrified vehicle according to embodiments of the present disclosure; and

FIG. 2 is a flowchart illustrating a method for providing a distance to empty of an electrified vehicle according to embodiments of the present disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. Fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, rom, ram, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a controller area network (CAN).

Unless specifically stated or obvious from context, as used herein, the term “about” is understood as within a range of normal tolerance in the art, for example within 2 standard deviations of the mean. “about” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Hereinafter, some embodiments of the present disclosure will be described in detail with reference to the exemplary drawings. In adding the reference numerals to the components of each drawing, it should be noted that the identical or equivalent component is designated by the identical numeral even when they are displayed on other drawings. Further, in describing the embodiment of the present disclosure, a detailed description of the related known configuration or function will be omitted when it is determined that it interferes with the understanding of the embodiment of the present disclosure.

Hereinafter, some embodiments of the present disclosure will be described in detail with reference to the exemplary drawings. In adding the reference numerals to the components of each drawing, it should be noted that the identical or equivalent component may be designated by the identical numeral even when they may be displayed on other drawings. Further, in describing the embodiment of the present disclosure, a detailed description of the related known configuration or function will be omitted when it may be determined that it interferes with the understanding of the embodiment of the present disclosure.

In describing the components of the embodiment according to the present disclosure, terms such as first, second, A, B, (a), (b), and the like may be used. These terms may be merely intended to distinguish the components from other components, and the terms do not limit the nature, order or sequence of the components. Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that may be consistent with their meaning in the context of the relevant art and will not be interpreted in an idealized or overly formal sense unless expressly so defined herein.

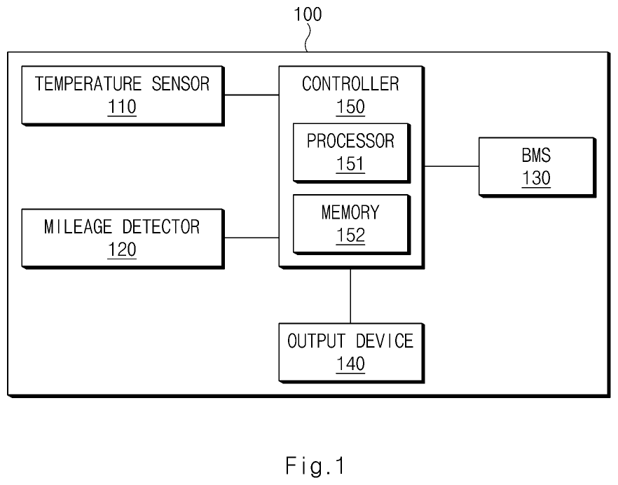

FIG. 1 is a block diagram illustrating an electrified vehicle according to embodiments of the present disclosure.

An electrified vehicle 100 refers to a vehicle that travels using an electric motor, such as an electric vehicle (EV), a plug-in hybrid electric vehicle (PHEV), and/or a hybrid electric vehicle (HEY). Referring to FIG. 1, the electrified vehicle (hereinafter, the vehicle) 100 may include a temperature sensor 110, a mileage detector 120, a battery management system (BMS) 130, an output device 140, a controller 150, and the like connected to each other through a vehicle network. The vehicle network may be implemented as a controller area network (CAN), a media oriented systems transport (MOST) network, a local interconnect network (LIN), an Ethernet, and/or an X-by-Wire (Flexray).

The temperature sensor 110 may be mounted on the vehicle 100 to measure a temperature of an outdoor air of the vehicle 100, that is, an ambient temperature. The temperature sensor 110 may include an element such as a thermostat and the like.

The mileage detector 120 may detect a distance that the vehicle 100 actually traveled, that is, an actual mileage. The mileage detector 120 may acquire (obtain) the actual mileage through an odometer or the like.

The BMS 130 may serve to maintain safety of a cell inside a battery (e.g., a high voltage battery) that supplies electric power required for a vehicle system, and reliability of a battery usage. The BMS 130 may monitor a voltage, a current, a temperature, and the like of the battery in real time using sensors. The BMS 130 may include a circuit for preventing overcharging or over-discharging during charging or discharging. The BMS 130 may calculate a state of charge (SOC) of the battery.

The output device 140 may output information in response to an instruction of the controller 150. For example, the output device 140 may display a distance to empty (DTE) of the vehicle. The output device 140 may output a progress, a result, and the like of an operation of the controller 150. The output device 140 may be implemented as at least one of devices such as a cluster, an audio video navigation (AVN) terminal, a display, and/or a touch screen.

The controller 150 may be a vehicle control unit (VCU) that is configured to control overall operations of the vehicle 100. The controller 150 may include at least one processor 151 and a memory 152. The at least one processor 151 may be a semiconductor device that processes instructions stored in the memory 152. The processor 151 may be implemented as at least one of processing devices such as an application specific integrated circuit (ASIC), a digital signal processor (DSP), a programmable logic device (PLD), a field programmable gate array (FPGA), a central processing unit (CPU), a microcontroller, and/or a microprocessor. The memory 152 may include various types of volatile or non-volatile storage media. For example, the memory 152 may be implemented as at least one of storage media (recording media) such as a flash memory, a hard disk, a secure digital card (SD card), a random access memory (RAM), a static random access memory (SRAM), a read only memory (ROM), a programmable read only memory (PROM), an electrically erasable and programmable ROM (EEPROM), an erasable and programmable ROM (EPROM), a register, a cache, and/or a removable disk. The memory 152 may store a lookup table, a fixed fuel efficiency, and the like. The fixed fuel efficiency, which may be a fuel efficiency settled for each vehicle model through a test, may be set in advance.

The controller 150 may calculate the DTE (an initial DTE) by multiplying the fixed fuel efficiency and a discharging amount. The discharging amount may vary depending on the battery SOC, and may vary based on a battery discharging amount when the battery SOC may be 100%, that is, when the battery may be fully charged. For example, when a nominal capacity of the battery may be 70 kWh, the discharging amount may be 66.5 kWh when the battery SOC may be displayed in the cluster as 100% (an actual SOC 95%), and the discharging amount may be 33.25 kWh when the battery SOC may be displayed in the cluster as 50%. When the battery may be fully charged (the battery SOC 100%), the discharging amount of the battery may change based on Min Cell learning.

The controller 150 may be configured to identify the ambient temperature based on a current weather using the temperature sensor 110 immediately after the vehicle may be started. The controller 150 may be configured to calculate a correction factor based on the ambient temperature. In this regard, the controller 150 may be configured to calculate the correction factor using a predefined correction factor calculation formula. In addition, the controller 150 may be configured to determine the correction factor matching the ambient temperature referring to the lookup table such as [Table 1] stored in the memory 152.

TABLE 1

| Ambient | | | | | | | |
|---|---|---|---|---|---|---|---|
| temperature [° C.] | −30 | −25 | −20 | −15 | −10 | −5 | 0 |
| Correction factor | −39.7% | −35.6% | −31.2% | −26.5% | −21.7% | −16.7% | −11.8% |

| Ambient | | | | | | |
|---|---|---|---|---|---|---|
| temperature [° C.] | 5 | 10 | 15 | 20 | 25 | 30 |
| Correction factor | −7.1% | −3.0% | 0.4% | 2.7% | 3.7% | 3.3% |

The controller 150 may be configured to calculate a final DTE using the fixed fuel efficiency, the discharging amount, and the correction factor. In other words, the controller 150 may be configured to calculate the final DTE by multiplying the DTE, which may be calculated by a product of the fixed fuel efficiency and the discharging amount, by the correction factor. The controller 150 may be configured to output the calculated final DTE on the output device 140. The controller 150 may be configured to identify the actual mileage through the mileage detector 120 when the vehicle 100 starts traveling. The controller 150 may be configured to update the final DTE by subtracting the actual mileage from the final DTE. For example, when the final DTE calculated immediately after starting the vehicle may be 80 km, the controller 150 may be configured to update the final DTE to 79 km by reducing 1 km from the final DTE when the vehicle 100 actually travels 1 km, and then may update the final DTE to 78 km by reducing 1 km from the final DTE when the vehicle 100 actually travels next 1 km.

The controller 150 may be configured to identify an actual discharging amount of the battery through monitoring of the battery SOC. The controller 150 may be configured to compare the actual discharging amount with a reference discharging amount when traveling a unit distance (e.g., 500 m). The controller 150 may adjust a DTE reduction rate based on the comparison result.

The controller 150 may be configured to identify the actual discharging amount through the BMS 130 when traveling the unit distance (e.g., 500 m). The controller 150 may compare the identified actual discharging amount with a reference discharging amount A corresponding to the actual mileage 500 m. For example, in a case in which the DTE may be 700 km when the discharging amount may be 70 kWh, the reference discharging amount may be 0.05 kWh corresponding to 500 m. In a case in which remaining energy of the battery may be 20 kWh when the DTE may be 100 km, the reference discharging amount may be calculated as 0.1 kWh (=(500 m×20 kWh)/100 km).

Specifically, the controller 150 may be configured to compare the actual discharging amount with a first reference discharging amount (=A×1.5). The controller 150 may determine a DTE reduction rate of when the actual discharging amount may be less than the first reference discharging amount as a first DTE reduction rate (e.g., 1 km reduction for each 1 km of the actual mileage).

When the actual discharging amount is not less than the first reference discharging amount, the controller 150 may be configured to compare the actual discharging amount with a second reference discharging amount (=A×3). The controller 150 may be configured to determine a DTE reduction rate of when the actual discharging amount may be equal to or greater than the first reference discharging amount and less than the second reference discharging amount as a second DTE reduction rate (e.g., 2 km reduction for each 1 km of the actual mileage).

When the actual discharging amount may be equal to or greater than the first reference discharging amount and may not be less than the second reference discharging amount, the controller 150 may be configured to compare the actual discharging amount with a third reference discharging amount (=A×4). The controller 150 may determine a DTE reduction rate of when the actual discharging amount may be equal to or greater than the second reference discharging amount and less than the third reference discharging amount as a third DTE reduction rate (e.g., 3 km reduction for each 1 km of the actual mileage).

The controller 150 may be configured to update the final DTE based on the determined DTE reduction rate. For example, the controller 150 may update the final DTE with the DTE obtained by subtracting 1 km, 2 km, or 3 km from the final DTE for every 1 km actual traveling based on the determined DTE reduction rate.

The controller 150 may be configured to output the final DTE on the output device 140. The controller 150 may be configured to display the final DTE in a form of visual information on the output device 140. When the final DTE reaches a value equal to or lower than a predetermined threshold, the controller 150 may output an auditory signal such as a warning sound and the like through a speaker while displaying the final DTE on the display.

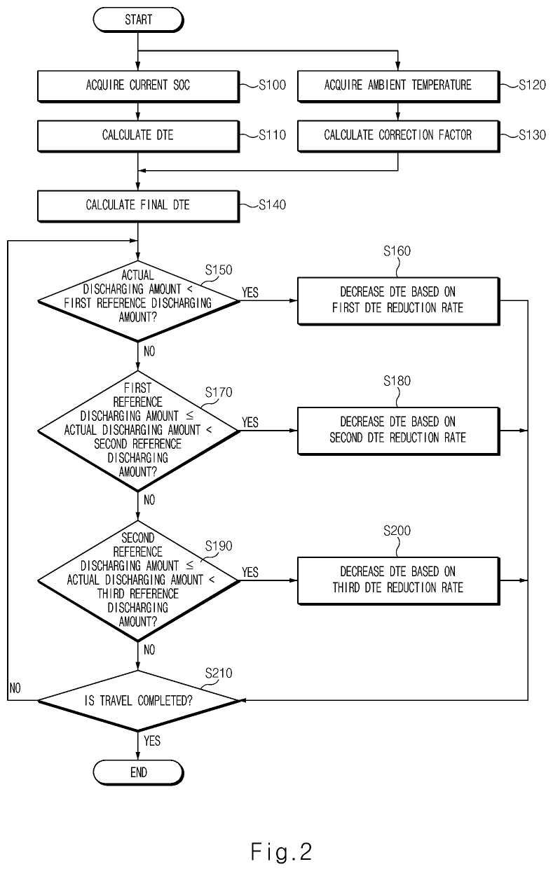

FIG. 2 is a flowchart illustrating a method for providing a distance to empty of an electrified vehicle according to embodiments of the present disclosure.

The controller 150 may acquire a current SOC of the battery when the vehicle 100 may be started (S100). The controller 150 may identify the current battery SOC through the BMS 130 when power may be applied to the vehicle 100.

The controller 150 may calculate the DTE (the initial DTE) using the acquired current SOC (S110). The controller 150 may determine a discharging amount matching the current SOC, and calculate the DTE by multiplying the determined discharging amount by the fixed fuel efficiency. In this regard, the fixed fuel efficiency, which is the fuel efficiency settled for each vehicle model, may be set in advance. The discharging amount may vary based on the battery SOC on the basis of the battery discharging amount of when the battery SOC is displayed as 100%. The discharging amount may be at a level of 95% of a target discharging amount and may have a margin of 5%. For example, in a case in which the discharging amount is 70 kWh when the battery SOC is displayed as 100%, the discharging amount may be 35 kWh when the battery SOC is 50%.

The controller 150 may identify the ambient temperature when the vehicle 100 is started (S120). The controller 150 may detect the ambient temperature of the vehicle 100 based on the current weather using the temperature sensor 110 immediately after the vehicle is started.

The controller 150 may calculate the correction factor based on the ambient temperature (S130). The controller 150 may calculate the correction factor using the predefined correction factor calculation formula. In addition, the controller 150 may determine the correction factor matching the ambient temperature referring to the lookup table stored in the memory 152.

The controller 150 may calculate the final D using the DTE calculated in S110 and the correction factor calculated in S130 (S140). The controller 150 may calculate the final DTE by multiplying the calculated DTE by the correction factor. That is, the controller 150 may calculate the DTE to which the ambient temperature is reflected. The controller 150 may output the calculated final DTE on the output device 140.

The controller 150 may determine whether the actual discharging amount of the vehicle 100 is less than the first reference discharging amount (S150). In this regard, the actual discharging amount means the battery discharging amount of when actually traveling the predetermined unit distance (e.g., 500 m). The first reference discharging amount may be determined by the reference discharging amount A. For example, the first reference discharging amount may be determined to be 1.5 times the reference discharging amount A. The reference discharging amount may be determined by the remaining energy of the battery and the current DTE. For example, in the case in which the remaining energy of the battery is 20 kWh when the DTE is 100 km, the reference discharging amount may be calculated as 0.1 kWh (=(500 m×20 kWh)/100 km).

When the actual discharging amount is less than the first reference discharging amount, the controller 150 may decrease the DTE based on the first DTE reduction rate (S160). When the actual discharging amount is less than the first reference discharging amount, the controller 150 may determine the first DTE reduction rate as the 1 km reduction for each 1 km of the actual mileage. Whenever the actual mileage increases by 1 km through the mileage detector 120, the controller 150 may update the DTE obtained by reducing 1 km from the final DTE as the final DTE. The controller 150 may output the updated final DTE on the output device 140.

When the actual discharging amount is not less than the first reference discharging amount in S150, the controller 150 may determine whether the actual discharging amount is equal to or greater than the first reference discharging amount and less than the second reference discharging amount (S170). The second reference discharging amount may be determined based on the reference discharging amount like the first reference discharging amount. For example, the second reference discharging amount may be determined to be three times the reference discharging amount.

When the actual discharging amount is equal to or greater than the first reference discharging amount and less than the second reference discharging amount, the controller 150 may reduce the DTE based on the second DTE reduction rate (S180). When the actual discharging amount is equal to or greater than the first reference discharging amount and less than the second reference discharging amount, the controller 150 may determine the second DTE reduction rate as the 2 km reduction for each 1 km of the actual mileage. Whenever the actual mileage increases by 1 km through the mileage detector 120, the controller 150 may update the D obtained by reducing 2 km from the final DTE as the final DTE. The controller 150 may output the updated final DTE on the output device 140.

When the actual discharging amount is equal to or greater than the first reference discharging amount and is not less than the second reference discharging amount in S170, the controller 150 may determine whether the actual discharging amount is equal to or greater than the second reference discharging amount and less than the third reference discharging amount (S190). The third reference discharging amount may be determined based on the reference discharging amount like the first reference discharging amount and the second reference discharging amount. For example, the third reference discharging amount may be determined to be 4 times the reference discharging amount.

When the actual discharging amount is equal to or greater than the second reference discharging amount and less than the third reference discharging amount, the controller 150 may reduce the DTE based on the third DTE reduction rate (S200). When the actual discharging amount is equal to or greater than the second reference discharging amount and less than the third reference discharging amount, the controller 150 may determine the third DTE reduction rate as the 3 km reduction for each 1 km of the actual mileage. Whenever the actual mileage increases by 1 km through the mileage detector 120, the controller 150 may update the DTE obtained by reducing 3 km from the final DTE as the final DTE. The controller 150 may output the updated final DTE on the output device 140.

When the actual discharging amount is equal to or greater than the second reference discharging amount and is not less than the third reference discharging amount, the controller 150 may determine whether the travel is completed (S210). In other words, when the actual discharging amount is equal to or greater than the third reference discharging amount, the controller 150 may determine whether the travel is completed. In addition, the controller 150 may determine whether the travel is completed after performing S160, S180, and S200. The controller 150 may terminate the DTE calculation when the travel is completed, and re-perform S150 and subsequent operations when the travel is not completed.

The description above is merely illustrative ofthe technical idea ofthe present disclosure, and various modifications and changes may be made by those skilled in the art without departing from the essential characteristics of the present disclosure. Therefore, the embodiments disclosed in the present disclosure are not intended to limit the technical idea of the present disclosure but to illustrate the present disclosure, and the scope of the technical idea of the present disclosure is not limited by the embodiments. The scope of the present disclosure should be construed as being covered by the scope of the appended claims, and all technical ideas falling within the scope of the claims should be construed as being included in the scope of the present disclosure.

Because the present disclosure calculates the distance to empty of the vehicle in consideration of the battery SOC and the ambient temperature, it may be possible to minimize the error (a travel error) between the distance to empty and the actual mileage caused by a sudden operation (driving) pattern change of a driver, a change in the weather or a road condition (a type), and the like.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. An electrified vehicle comprising:
a temperature sensor configured to measure an ambient temperature of the electrified vehicle;
a battery management system (BMS) configured to monitor a state of charge (SOC) of a battery mounted on the electrified vehicle; and
a controller configured to:
calculate a distance to empty (DTE) based on the ambient temperature and the SOC of the battery;
adjust a DTE reduction rate based on an actual discharging amount of the battery while traveling; and
update the DTE based on the DTE reduction rate after the DTE reduction rate is adjusted.

2. The electrified vehicle of claim 1, wherein the controller is configured to:
calculate an initial DTE based on a discharging amount matching the SOC of the battery and a fixed fuel efficiency of the vehicle;
calculate a correction factor based on the ambient temperature; and
calculate the DTE based on the initial DTE and the correction factor.

3. The electrified vehicle of claim 2, wherein the discharging amount matching the SOC of the battery is determined based on a battery discharging amount of when the battery is fully charged.

4. The electrified vehicle of claim 1, wherein the controller is configured to:
compare the actual discharging amount of the battery with a first reference discharging amount; and
determine the D reduction rate as a first D reduction rate when the actual discharging amount of the battery is less than the first reference discharging amount.

5. The electrified vehicle of claim 4, wherein the controller is configured to:
compare the actual discharging amount of the battery with a second reference discharging amount when the actual discharging amount of the battery is equal to or greater than the first reference discharging amount; and
determine the DTE reduction rate as a second DTE reduction rate when the actual discharging amount of the battery is less than the second reference discharging amount.

6. The electrified vehicle of claim 5, wherein the controller is configured to:
compare the actual discharging amount of the battery with a third reference discharging amount when the actual discharging amount of the battery is equal to or greater than the second reference discharging amount; and
determine the DTE reduction rate as a third DTE reduction rate when the actual discharging amount of the battery is less than the third reference discharging amount.

7. The electrified vehicle of claim 6, wherein the first reference discharging amount, the second reference discharging amount, and the third reference discharging amount are determined based on remaining energy of the battery and a reference discharging amount determined by the DTE.

8. The electrified vehicle of claim 1, wherein the controller is configured to decrease the DTE with the D reduction rate and then update the DTE with a reduced DTE whenever the vehicle actually travels a predetermined distance.

9. The electrified vehicle of claim 1, further comprising an output device for displaying the DTE.

10. The electrified vehicle of claim 9, wherein the output device includes at least one of a cluster, an AVN terminal, a display, or a touch screen.

11. A method for providing a distance to empty of an electrified vehicle, the method comprising:
calculating a DTE based on a SOC of a battery mounted on the vehicle and an ambient temperature of the vehicle;
adjusting a DTE reduction rate based on an actual discharging amount of the battery while traveling; and
updating the DTE based on the DTE reduction rate after the DTE reduction rate is adjusted.

12. The method of claim 11, wherein the calculating of the DTE includes:
acquiring the SOC of the battery through a BMS;
calculating an initial DTE based on a discharging amount matching the SOC of the battery and a fixed fuel efficiency of the vehicle;
calculating a correction factor based on the ambient temperature acquired by a temperature sensor; and
calculating the DTE based on the initial DTE and the correction factor.

13. The method of claim 12, wherein the discharging amount matching the SOC of the battery is determined based on a battery discharging amount of when the battery is fully charged.

14. The method of claim 11, wherein the adjusting of the DTE reduction rate includes:
comparing the actual discharging amount of the battery with a first reference discharging amount; and
determining the DTE reduction rate as a first DTE reduction rate when the actual discharging amount of the battery is less than the first reference discharging amount.

15. The method of claim 14, wherein the adjusting of the DTE reduction rate includes:
comparing the actual discharging amount of the battery with a second reference discharging amount when the actual discharging amount of the battery is equal to or greater than the first reference discharging amount; and
determining the DTE reduction rate as a second DTE reduction rate when the actual discharging amount of the battery is less than the second reference discharging amount.

16. The method of claim 15, wherein the adjusting of the DTE reduction rate includes:
comparing the actual discharging amount of the battery with a third reference discharging amount when the actual discharging amount of the battery is equal to or greater than the second reference discharging amount; and
determining the DTE reduction rate as a third DTE reduction rate when the actual discharging amount of the battery is less than the third reference discharging amount.

17. The method of claim 16, wherein the first reference discharging amount, the second reference discharging amount, and the third reference discharging amount are determined based on remaining energy of the battery and a reference discharging amount determined by the DTE.

18. The method of claim 11, wherein the updating of the DTE includes:
decreasing the DTE with the DTE reduction rate and then updating the DTE with a reduced DTE whenever the vehicle actually travels a predetermined distance.
